(19) United States
(12) Patent Application Publication
(10) Pub. No.: US 2006/0289912 A1
(43) Pub. Date: Dec. 28, 2006

(54) CMOS image sensor and manufacturing method thereof

(76) Inventor: Kim Sang Sik, Suwon-si (KR)

Correspondence Address: Jeff Lloyd;Saliwanchik, Lloyd & Saliwanchik, A Professional Association, P.O. Box 142950, Gainesville, FL, 32614-2950, US

(21) Appl. No.: 11/475,378

(22) Filed: Jun. 27, 2006

(30) Foreign Application Priority Data
Jun. 27, 2005 (KR) 10-2005-0055590

(51) Int. Cl. H01L 31/113

(52) U.S. Cl. 257/292

(57) ABSTRACT

Provided are a CMOS image sensor and a manufacturing method thereof. The CMOS image sensor incorporates an interlayer insulating layer, a color filter layer, a first planarizing layer, and at least one microlens. The interlayer insulating layer is formed on a semiconductor substrate having at least one photodiode. The color filter layer is formed above the interlayer insulating layer and incorporates at least one color filter. The first planarizing layer is formed on the color filter layer, and has a uniform surface tension from being UV radiated after a hardening process. The at least one microlens is formed on the first planarizing layer to correspond to the at least one photodiode.

### RELATED APPLICATION

This application claims the benefit under 35 U.S.C. §119(e) of Korean Patent Application Number 10-2005-0055590, filed Jun. 27, 2005, which is incorporated herein by reference in its entirety.

### FIELD OF THE INVENTION

The present invention relates to a complementary metal oxide semiconductor (CMOS) image sensor and a manufacturing method thereof.

### BACKGROUND OF THE INVENTION

In general, an optical image sensor is a semiconductor device that converts an optical image into an electrical signal. Optical image sensors are roughly classified into charge coupled devices (CCDs) and complementary metal oxide semiconductors (CMOSs).

Since the CCD has a complicated driving method, consumes much power, and requires a multi-step photolithography process, the manufacturing process of the CCD is complicated. In order to overcome the drawbacks of the CCD, the CMOS image sensor is favored as a next generation image sensor in the industry.

A CMOS image sensor incorporates a photo diode and a MOS transistor inside a pixel unit, and employs a switching method to detect the electrical signal of each pixel unit in sequence to form an image.

Below, a manufacturing method of a CMOS image sensor according to the related art will be described with reference to the accompanying drawings.

FIGS. 1A through 1C are sectional views showing a manufacturing process of a CMOS image sensor according to the related art.

Referring to FIG. 1A, a plurality of light detecting modules, for example, photodiodes 11 are formed on a semiconductor substrate (not shown), on which an interlayer insulating layer 12 is formed.

Then, after a dye resist is coated on the interlayer insulating layer 12, exposure and development processes are performed to form a color filter layer 14 consisting of filters for filtering light for each wavelength.

Next, a planarizing layer 15 is formed on the color filter layer 14 in order to obtain a flat surface for adjusting the focal distance and forming a lens layer.

Subsequently, the planarizing layer 15 is hardened through a heat treatment at a temperature over 200° C.

Next, referring to FIG. 1B, a resist layer 16a for forming a microlens is coated on the planarizing layer 15, and a reticle 17 having openings is aligned on the resist layer 16a.

Then a laser is illuminated onto the entire surface of the reticle 17 using the reticle 17 for a mask to selectively expose the resist layer 16a that corresponds to the openings of the reticle 17.

Referring to FIG. 1C, the exposed resist layer 16a is developed to form a microlens pattern. The microlens pattern is then made to reflow at a predetermined temperature to form the microlens 16.

However, when the microlens 16 is formed to be of a larger size in order to increase its ability to condense light, unevenness of the surface tension on the planarizing layer 15 during the hardening of the planarizing layer 15 causes overlapping regions (A) or wide gaps (B) between neighboring microlenses 16.

That is, the heat treatment for hardening the planarizing layer causes the physical properties of the surface of the planarizing layer to change due to substances from solvent used in a closed oven. Consequently, the reflow ability of the microlens pattern formed on the planarizing layer becomes uneven, and the formation of the microlenses in a uniform state on the entire wafer becomes difficult. When the unevenness (of regions A and B) is severe, a defective microlens is formed, decreasing yield of the image sensor.

### SUMMARY OF THE INVENTION

Accordingly, the present invention is directed to a CMOS image sensor and a manufacturing method thereof that addresses and/or substantially obviates one or more problems, limitations, and/or disadvantages of the related art.

An object of the present invention is to provide a CMOS image sensor and a manufacturing method thereof for increasing the evenness of a microlens by correcting the uniformities of surface tensions of a planarizing layer during its hardening process, and increasing yield and reliability of the image sensor by preventing defects of the microlens.

To achieve these objects and other advantages and in accordance with the purpose of the invention, as embodied and broadly described herein, there is provided a CMOS image sensor incorporating: an interlayer insulating layer formed on a semiconductor substrate incorporating at least one photodiode; a color filter layer formed on the interlayer insulating layer incorporating at least one color filter having a predetermined length; a UV radiated first planarizing layer having a uniform surface tension formed on the color filter layer, and at least one microlens formed on the UV radiated first planarizing layer opposite the at least one photodiode.

In another aspect of the present invention, there is provided a manufacturing method of a CMOS image sensor including: forming an interlayer insulating layer on a semiconductor substrate incorporating at least one photodiode; forming a color filter layer incorporating at least one color filter having a predetermined length on the interlayer insulating layer; forming a first planarizing layer on the color filter layer; performing a heat treatment process to harden the first planarizing layer, radiating UV rays onto the hardened first planarizing layer; and forming at least one microlens on the UV radiated hardened first planarizing layer opposite the at least one photodiode.

It is to be understood that both the foregoing general description and the following detailed description of the present invention are exemplary and explanatory and are intended to provide further explanation of the invention as claimed.

### BRIEF DESCRIPTION OF THE DRAWINGS

The accompanying drawings, which are included to provide a further understanding of the invention and are incorporated in and constitute a part of this application, illustrate embodiment(s) of the invention and together with the description serve to explain the principle of the invention. In the drawings:

FIGS. 1A through 1C are sectional views showing a manufacturing process of a CMOS image sensor according to the related art.

FIGS. 2A through 2D are sectional views showing a manufacturing process of a CMOS image sensor according to an embodiment of the present invention.

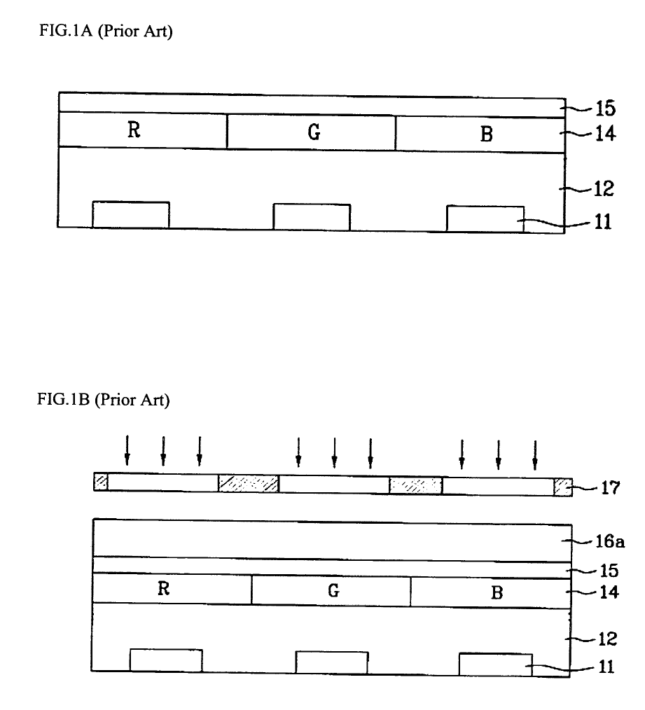

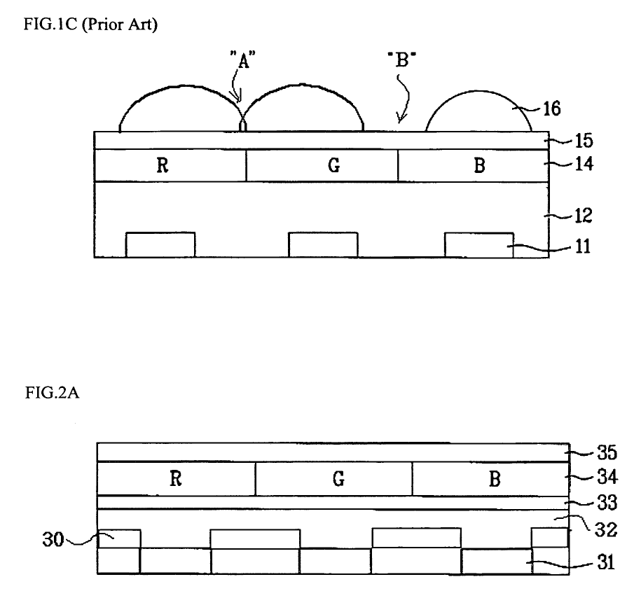

### DETAILED DESCRIPTION OF THE INVENTION

Reference will now be made in detail to the preferred embodiments of the present invention, examples of which are illustrated in the accompanying drawings.

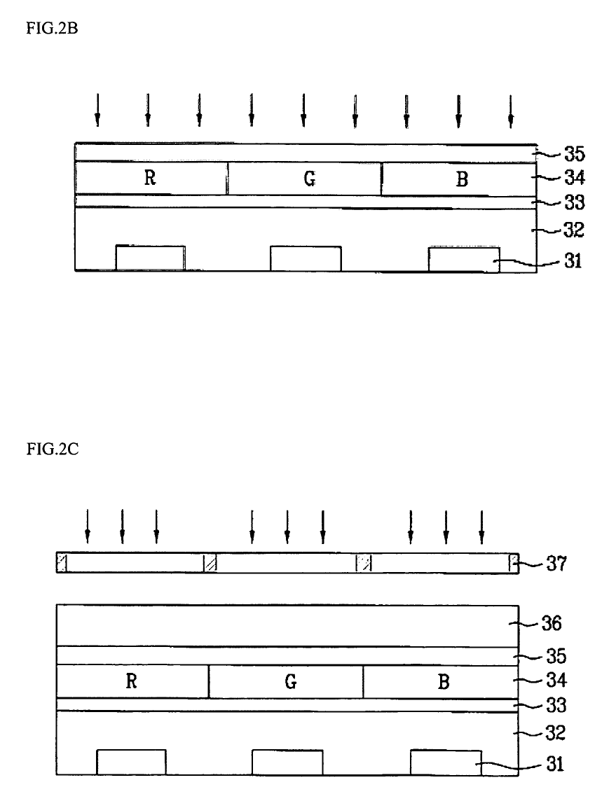

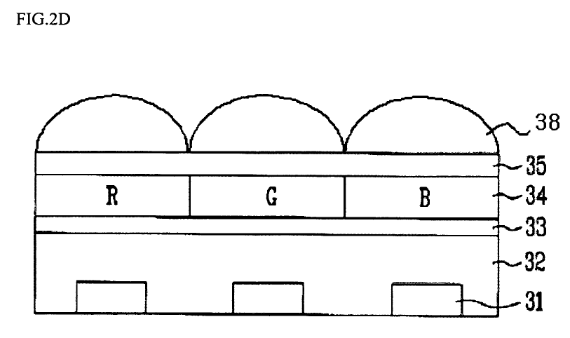

FIGS. 2A through 2D are sectional views showing a manufacturing process of a CMOS image sensor according to an embodiment of the present invention.

Referring to FIG. 2A, an interlayer insulating layer 32 is formed over the entire surface of a semiconductor substrate with one or more photodiodes 31 formed thereon. The photodiodes 31 generate a charge according to the amount of incident light and can be formed by any known methods.

In one embodiment, the interlayer insulating layer 32 can be formed as a multi layer. In another embodiment, the interlayer insulating layer 32 can incorporate a light blocking layer 30 for blocking incident light between photodiode regions. In such an embodiment, a first interlayer insulating layer can be formed on the substrate and photodiodes 31, upon which the light blocking layer 30 is then formed, and a second interlayer insulating layer can be formed thereupon.

In a further embodiment, a second planarizing layer 33 can be formed on the interlayer insulating layer 32 to protect the latter from moisture and scratches.

The second planarizing layer 33 can be an organic layer. In one embodiment, the second planarizing layer 33 can be deposited as a thin film with a thickness of about 50 nm and less, which is then hard cured.

In a specific embodiment, the first planarizing layer 33 can be formed of an organic substance having superior transparency to visible ray wavelengths in order to maintain the profile and evenness of the color filter layer 34 to be formed later.

Then, a dye resist can be applied on the second planarizing layer 33 and patterned to form color filter layers of R, G, and B for filtering respective wavelengths of light.

In a specific embodiment, the color filter layer 34 can be completed by performing photolithography in three stages to form the color filters for each color—red (R), green (G), and blue (B).

In a further embodiment, after the color filters for each color—R, G, and B—are formed, a UV exposure process can be performed to create an improved surface stability.

Then, a first planarizing layer 35 can be formed. In one embodiment the first planarizing layer 35 can have a thickness of 0.5-1.5 μm. Embodiments of the first planarizing layer 35 can be formed to ensure evenness in order to adjust the focal point and form a lens layer on the color filter layer 34.

In an embodiment, the first planarizing layer 35 can be hardened by performing a heat treatment at a temperature of between 150-300° C.

During the hardening of the first planarizing layer 35, the upper surface of the first planarizing layer 35 can become unstable due to an out-gassing phenomenon.

In order to compensate for the surface tension instability of the first planarizing layer 35 caused by the out-gassing phenomenon, embodiments of the subject invention provide UV radiation across the entire surface of the first planarizing layer 35.

Referring to FIG. 2B, UV rays can be radiated onto the entire surface of the first planarizing layer 35.

In a specific embodiment, the UV rays radiated onto the first planarizing layer 35 can have a wavelength between 350 nm-450 nm.

By using a UV wavelength of 350 nm-450 nm, the first planarizing layer 35 can be stabilized before forming the microlens 38. Embodiments of the subject invention can use exposure wavelengths of an I-line of 365 nm, an H-line of 405 nm, or a G-line of 436 nm. Stabilizing the first planarizing layer 35 facilitates forming the microlenses 38.

In a specific embodiment, the energy of the UV rays radiated onto the first planarizing layer 35 can be 0.1-1 joule. By radiating a UV energy of 0.1-1 joule on the first planarizing layer 35 in the present invention, the first planarizing layer 35 can be optimally stabilized.

Accordingly, the UV rays radiated on the first planarizing layer 35 can improve the surface characteristics of a first planarizing layer 35 having regionally varying surface characteristics, and can induce a uniform surface tension to allow an even fluidity of the microlens formed on the first planarizing layer 35.

Referring to FIG. 2C, a resist layer 36 for a microlens can be applied to the first planarizing layer 35. A reticle 37 having an opening can then be arranged above the resist layer 36.

In one embodiment, the reticle 37 can be used as a mask when a laser is emitted onto the entire surface of the reticle 37 to selectively expose the resist layer 36 opposite the opening of the reticle 37.

Referring to FIG. 2D, the exposed resist layer 36 can be developed, and a microlens pattern formed.

After the microlens pattern is formed, a floor exposure can be performed in order to bleach any absorbed material of the photo active compound (PAC) present in the microlens pattern.

Then, the microlens pattern can be made to reflow at a predetermined temperature to form a plurality of microlenses 38.

In a specific embodiment, in order to form the microlenses 38, the reflowing can be performed at a temperature of 300-700° C.

The microlenses 38 can be formed in a number corresponding to the number of pixels of the image sensor or the number of photodiodes 31. In addition, the size of the microlenses 38 can easily be formed larger to let in more incident light.

In the manufacturing method of the CMOS image sensor according to the present invention, UV rays can be radiated on the first planarizing layer 35 to make the surface tension even for forming the microlenses 38. Because the UV process prevents bridges between closely neighboring microlenses 38, the microlenses can be uniformly formed even when the size of the microlenses 38 is increased.

The advantages of the above-described CMOS image sensor and the manufacturing method thereof according to the present invention will now be set forth.

Specifically, when the top surface of the planarizing layer is subjected to an unstable environment due to out-gassing thereof during the hardening of the planarizing layer, the uneven surface tension of the planarizing layer caused by the out-gassing can be compensated for. In particular, UV rays can be radiated on the planarizing layer to reduce locally uneven surface areas and induce a uniform surface tension. Thus, the microlenses formed thereabove can have an even fluidity.

Additionally, the present invention simplifies the forming of the microlenses and also their evenness, so that their sensitivity and uniformity are increased as well as their color reproduction, for an increased product yield and reliability.

It will be apparent to those skilled in the art that various modifications and variations can be made in the present invention. Thus, it is intended that the present invention covers the modifications and variations of this invention provided they come within the scope of the appended claims and their equivalents.

I claim:

1. A CMOS (complementary metal oxide semiconductor) image sensor comprising:
an interlayer insulating layer formed on a semiconductor substrate having at least one photodiode;
a color filter layer formed above the interlayer insulating layer, wherein the color filter layer comprises one or more color filters;
a first planarizing layer having uniform surface tension formed on the color filter layer; and
at least one microlens formed on the first planarizing layer, each microlens corresponding to one of the at least one photodiode.

2. The CMOS image sensor according to claim 1, wherein the first planarizing layer is UV radiated to provide the uniform surface tension after the first planarizing layer is hardened.

3. The CMOS image sensor according to claim 1, wherein the planarizing layer is formed at a thickness of 0.5-1.51 μm.

4. The CMOS image sensor according to claim 1, wherein UV ray radiation is performed on the color filter layer to improve a surface stability of each of the one or more color filters.

5. The CMOS image sensor according to claim 1, further comprising a second planarizing layer formed on the interlayer insulating layer and below the color filter layer, wherein the second planarizing layer comprises an organic material.

6. The CMOS image sensor according to claim 5, wherein the second planarizing layer is formed at a thickness of approximately 50 nm and less.

7. The CMOS image sensor according to claim 1, further comprising a light blocking layer formed within the interlayer insulating layer, wherein the light blocking layer blocks light incident regions of the substrate not having the at least one photodiode.

8. A manufacturing method of a CMOS image sensor, the method comprising:
forming an interlayer insulating layer on a semiconductor substrate having at least one photodiode;
forming a color filter layer above the interlayer insulating layer;
forming a first planarizing layer on the color filter layer;
performing a heat treatment process to harden the first planarizing layer;
radiating UV (ultra violet) rays onto the hardened first planarizing layer; and
forming at least one microlens on the UV radiated hardened first planarizing layer, each microlens corresponding to one of the at least one photodiode.

9. The manufacturing method according to claim 8, wherein the first planarizing layer is formed at a thickness of 0.5-1.5 μm.

10. The manufacturing method according to claim 8, wherein forming a color filter layer comprises:
forming a red, a green, and a blue color filter in the color filter layer by performing a three-step photolithography process, each step for a corresponding color filter; and
performing a UV ray exposure process on the surface of the color filter layer for improving a surface stability thereof.

11. The manufacturing method according to claim 8, further comprising forming a second planarizing layer formed of an organic material after forming the interlayer insulating layer, but before forming the color filter layer.

12. The manufacturing method according to claim 11, wherein the second planarizing layer is formed at a thickness of 50 nm and less.

13. The manufacturing method according to claim 8, wherein performing a heat treatment process comprises hardening the first planarizing layer at a temperature of 150-300° C.

14. The manufacturing method according to claim 8, wherein forming at least one microlens comprises:
coating a resist layer on the first planarizing layer;
patterning the resist layer through an exposure and development process; and
performing a reflow process of the patterned resist layer.

15. The manufacturing method according to claim 14, wherein performing a reflow process is performed at a temperature of 300-700° C.

16. The manufacturing method according to claim 8, further comprising forming a light blocking layer within the interlayer insulating layer, wherein the interlayer insulating layer comprises a plurality of interlayer insulating layers,
wherein forming the interlayer insulating layer and forming the light blocking layer within the interlayer insulating layer comprises:
forming a first interlayer insulating layer of the plurality of interlayer insulating layers,
forming a light blocking layer on the first interlayer insulating layer not above the at least one photodiode, wherein the light blocking layer blocks light incident regions of the substrate not having the at least one photodiode, and
forming a second interlayer insulating layer of the plurality of interlayer insulating layers on the first interlayer insulating layer and the light blocking layer.

17. The manufacturing method according to claim 8, wherein radiating UV rays onto the hardened first planarizing layer improves surface characteristics of the first planarizing layer having locally different surface characteristics, and induces an uniform surface tension of the first planarizing layer.

18. The manufacturing method according to claim 8, wherein radiating UV rays onto the hardened first planarizing layer comprises radiating UV rays having a wavelength ranging from 350 nm-450 nm.

19. The manufacturing method according to claim 8, wherein radiating UV rays onto the hardened first planarizing layer comprises using UV energy of 0.1 joule-1 joule.
